(19) United States
(12) Patent Application Publication
(10) Pub. No.: US 2023/0020481 A1
(43) Pub. Date: Jan. 19, 2023

(54) DISPLAY MODULE, MANUFACTURE METHOD THEREOF AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Chaoxue QIN, Beijing (CN); Rongkun FAN, Beijing (CN); Jialin WANG, Beijing (CN); Fei ZENG, Beijing (CN); Jia DENG, Beijing (CN); Guodong ZHOU, Beijing (CN); Tianjun DENG, Beijing (CN); Xiaolong TANG, Beijing (CN)

(21) Appl. No.: 17/904,746

(22) PCT Filed: Oct. 26, 2021
(86) PCT No.: PCT/CN2021/126303

§ 371 Date: Aug. 22, 2022

(30) Foreign Application Priority Data
Jan. 27, 2021 (CN) 202110112174.7

(51) Int. Cl. H01L 33/64; H01L 33/00

(52) U.S. Cl. CPC H01L 33/642; H01L 33/005; H01L 33/641; H01L 2933/0075

(57) ABSTRACT

An embodiment of the present disclosure provides a display module, including a display panel: a cover plate on a light-emitting side of the display panel; and a heat dissipation layer on a back side of the display panel. The back side faces away from the light-emitting side. Edges of the cover plate, the display panel and the heat dissipation layer are bent toward the back side of the display panel to form a shape-matched arc surface. The display panel further includes a planar portion and edges surrounding the planar portion. At least part of an edge of an orthographic projection of the display module on a plane where the planar portion of the display panel is located is arc. The heat dissipation layer includes a stretchable structure in an arc surface region having an arc edge.

### TECHNICAL FIELD

Embodiments of the present disclosure belong to the field of display technology, and in particular relates to a display module, a manufacture method thereof, and a display apparatus.

### BACKGROUND

At present, OLED flexible display devices that are bendable, folding, and stretchable are under active development. In the existing art, an edge region at a display side of the display screen has an arc surface, the display screen has rounded corners, and a heat dissipation film is attached to a back side of the display screen to timely transfer and release heat generated during display of the display screen. When the heat dissipation film is attached to the peripheral corners with curved surfaces, the four corner of the heat dissipation film are in a compressed state. Since the heat dissipation film itself is not stretchable, a redundant portion of the heat dissipation film tends to form pleats, causing bubbles between the heat dissipation film and the display screen, and pleats formed when the heat dissipation film is attached tend to cause cracks or other defects in the display screen.

### SUMMARY

Embodiments of the present disclosure provide a display module, a manufacture method thereof, and a display apparatus.

In a first aspect, an embodiment of the present disclosure provides a display module including a display panel; a cover plate on a light-emitting side of the display panel; and a heat dissipation layer on a back side of the display panel; wherein the back side faces away from the light-emitting side. Edges of the cover plate, edges of the display panel and edges of the heat dissipation layer are bent toward the back side of the display panel to form a shape-matched arc surface. The display panel further includes a planar portion, and the edges of the display panel surround the planar portion. At least part of an edge of an orthographic projection of the display module on a plane where the planar portion of the display panel is located is arc. The heat dissipation layer includes a stretchable structure in an arc surface region with an arc edge.

In some embodiments, the heat dissipation layer includes a thermal conductive film, and the stretchable structure includes a through hole in the thermal conductive film.

In some embodiments, the stretchable structure includes a plurality of through holes, and the plurality of through holes are arranged in an array along an extending direction of the arc edge.

In some embodiments, the plurality of through holes are evenly spaced apart from each other in the arc surface region having the arc edge.

In some embodiments, the through holes in the arc surface region having the arc edge have a same cross sectional area, and a distance between the through holes proximal to a center of the heat dissipation layer is greater than a distance between the through holes away from the center of the heat dissipation layer.

In some embodiments, the through holes in the arc surface region having the arc edge have a same distance therebetween, and a cross sectional area of the through holes proximal to a center of the heat dissipation layer is smaller than a cross sectional area of the through holes away from the center of the heat dissipation layer.

In some embodiments, a size of each of the plurality of through holes ranges from 0.5 to 1.5 mm.

In some embodiments, an orthographic projection of each of the plurality of through holes on the display panel has any one or more shapes of a circle, an ellipse, a rectangle, a diamond or a regular polygon.

In some embodiments, the thermal conductive film includes any one of copper, aluminum, silver, or gold.

In some embodiments, the heat dissipation layer further includes an electromagnetic shielding film, and the electromagnetic shielding film is on a side of the thermal conductive film away from the display panel, and covers at least the through hole in the thermal conductive film.

In some embodiments, the electromagnetic shielding film includes any one of copper, aluminum, silver, or gold.

In some embodiments, the heat dissipation layer further includes a protective film, the protective film disposed is on a side of the electromagnetic shielding film away from the display panel, and an orthographic projection of the protective film on the display panel overlaps an orthographic projection of the electromagnetic shielding film on the display panel.

In some embodiments, a portion of the protective film in the arc surface region having the arc edge has a gradually decreased thickness in a direction from an end away from the arc edge toward the arc edge.

In some embodiments, a portion of the protective film in the arc surface region having the arc edge has a smaller thickness than other portions of the protective film.

In some embodiments, the protective film includes polyolefin.

In some embodiments, the heat dissipation layer further includes an adhesive film, the adhesive film is on a side of the thermal conductive film proximal to the display panel, and an orthographic projection of the adhesive film on the display panel overlaps an orthographic projection of the electromagnetic shielding film on the display panel.

In some embodiments, a portion of the adhesive film in the arc surface region having the arc edge has a gradually decreased thickness in a direction from an end away from the arc edge toward the arc edge.

In some embodiments, a portion of the adhesive film in the arc surface region having the arc edge has a smaller thickness than other portions of the adhesive film.

In some embodiments, the adhesive film includes a stretchable adhesive material.

In a second aspect, an embodiment provides a display apparatus including the display module described above.

In a third aspect, an embodiment provides a method for manufacturing a display module, including: preparing a cover plate, such that edges of the cover plate are bent towards a side of the cover plate to form an arc surface; preparing a display panel; preparing a heat dissipation layer; disposing the display panel on an inner side of the cover plate with the display panel being shape-matched with the cover plate; wherein the inner side of the cover plate is an inner side of the arc surface, and the cover plate is on a light-emitting side of the display panel, and the display panel includes a planar portion and edges surrounding the planar portion; and disposing a heat dissipation layer on a back side of the display panel with the heat dissipation layer being shape-matched with the display panel; wherein the back side of the display panel faces away from the light-emitting side of the display panel. At least part of an edge of an orthographic projection of the display module on a plane where the planar portion of the display panel is located is arc, and preparing the heat dissipation layer includes: preparing a stretchable structure in an arc surface region having an arc edge of the heat dissipation layer.

In some embodiments, preparing the heat dissipation layer includes preparing a thermal conductive film, and preparing the stretchable structure including forming a through hole in the thermal conductive film through an etching or punching process.

### BRIEF DESCRIPTION OF DRAWINGS

Accompanying drawings are provided for further understanding of the embodiments of the present disclosure and constitute a part of the specification. Hereinafter, these drawings are intended to explain the present disclosure together with the following embodiments, but should not be considered as a limitation to the present disclosure. The above and other features and advantages will become more apparent to those skilled in the art through detailed description of the exemplary embodiments with reference to the accompanying drawings, in which:

FIG. 1 is a schematic diagram showing a structure of a display screen in the existing art;

FIG. 2 is a sectional view showing a structure of a heat dissipation layer according to the existing art;

FIG. 3 is a top view showing a structure of a display module according to an embodiment of the present disclosure;

FIG. 4 is a sectional view showing a structure of the display module in FIG. 3 along line AA;

FIG. 5 is a top view showing a structure of another display module according to an embodiment of the present disclosure;

FIG. 6 is a top view showing a structure of yet another display module according to an embodiment of the present disclosure;

FIG. 7 is a top view showing a structure of a heat dissipation layer according to an embodiment of the present disclosure;

FIG. 8 is a sectional view showing a structure of the heat dissipation layer in FIG. 7 along line BB;

FIG. 9 is an enlarged top view of a thermal conductive film portion C in the heat dissipation layer of FIG. 7;

FIG. 10 is another enlarged top view of a portion C of the thermal conductive film in the heat dissipation layer of FIG. 7;

FIG. 11 is yet another enlarged top view of a portion C of the thermal conductive film in the heat dissipation layer of FIG. 7;

FIG. 12 is a sectional view showing a structure of the heat dissipation layer in FIG. 3 along line AA;

FIG. 13 is sectional view showing another structure of the heat dissipation layer in FIG. 3 along line AA;

FIG. 14 is a sectional view showing yet another structure of the heat dissipation layer in FIG. 3 along line AA;

FIG. 15 is a sectional view showing yet another structure of the heat dissipation layer in FIG. 3 along line AA; and

FIG. 16 is a sectional view showing a structure of the display panel in FIG. 3 along line AA.

The reference signs therein are listed below:

1. display panel; 101. light-emitting side; 102. back side; 11. flexible base substrate; 12. pixel circuit layer; 13. light-emitting element; 14. encapsulation layer; 15. touch electrode layer; 16. polarizer; 6. optical clear adhesive (OCA); 2. cover plate; 3. heat dissipation layer; 103. arc surface region with arc edge; 300. stretchable structure; 31. thermal conductive film; 301. through hole; 32. electromagnetic shielding film; 33. protective film; 34. adhesive film; 4. display screen; 35. copper foil; 36. release film; and 5. pleat.

### DETAIL DESCRIPTION OF EMBODIMENTS

In order to make those skilled in the art better understand the technical solutions in the embodiments of the present disclosure, the display module, the manufacture method thereof and the display apparatus provided in the embodiments of the present disclosure will be described in further detail below with reference to the accompanying drawings and specific implementations.

Embodiments of the present disclosure will be described more sufficiently below with reference to the accompanying drawings, but which may be embodied in different forms and should not be construed as limited to the embodiments set forth in the present disclosure. Rather, these embodiments are provided so that this disclosure will be thorough and complete, and will fully convey the scope of the present disclosure to those skilled in the art.

The embodiments of the present disclosure are not limited to the embodiments shown in the drawings, but include modifications of configurations formed based on a manufacturing process. Thus, the regions illustrated in the figures have schematic properties, and the shapes of the regions shown in the figures illustrate specific shapes of regions, but are not intended to be limitative.

In order to realize bezel-less full-screen display, an edge region around a display side of a display screen is typically set to an arc surface, and corners of the display screen are shaped into round, so that during display, peripheral corners of the whole display screen can also display images, thereby realizing bezel-less full-screen display while increasing an effective display area of the display screen.

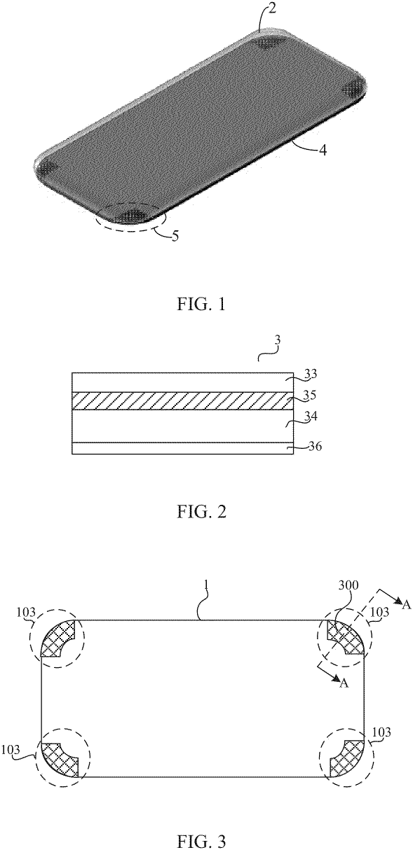

As shown in FIG. 1, in the manufacture of the display screen 4 that is capable of displaying at peripheral corners, a bendable and deformable flexible display screen is typically disposed on an inner side of a glass cover plate 2 which has peripherys bent into arc surfaces, and then a heat dissipation layer is attached to a side of the display screen 4 away from the glass cover plate 2 to timely transfer and release heat generated during display of the display screen. As shown in FIG. 2, a heat dissipation layer 3 generally includes a one-piece copper foil 35, a protective film 33 on one side of the copper foil 35, and an adhesive film 34 on the other side of the copper foil 35. A release film 36 is further attached to a side of the adhesive film 34 away from the copper foil 35. The copper foil 35 mainly plays a role in heat conduction and dissipation. The protective film 33 is configured to protect the copper foil 35 from being corroded and damaged due to exposure. The adhesive film 34 is configured to bond and attach the heat dissipation layer 3 and the display screen 4 to each other. The release film 36 is configured to protect the adhesive film 34 from adhesive failure, and the release film 36 is peeled off when the heat dissipation layer 3 is attached to the display screen 4.

When the heat dissipation layer 3 is attached to the peripheral corner regions having the curved surfaces of the display screen, since an area of regions of the heat dissipation layer 3 where the four corners are located is greater than an area of regions, where the curved arc surfaces are located, at the four corners of the glass cover plate, and since the heat dissipation layer 3 itself is not stretchable, a redundant portion of the heat dissipation layer 3 generated when the four corners of the heat dissipation layer 3 are in a compressed state tends to form pleats 5, causing bubbles between the heat dissipation layer 3 and the display screen 4, and meanwhile, during attachment of the heat dissipation layer 3, the pleats 5 of the heat dissipation layer may press against the display screen during the attaching process, causing cracks or other defects in the display screen 4 and severely affect the display quality of the display screen 4.

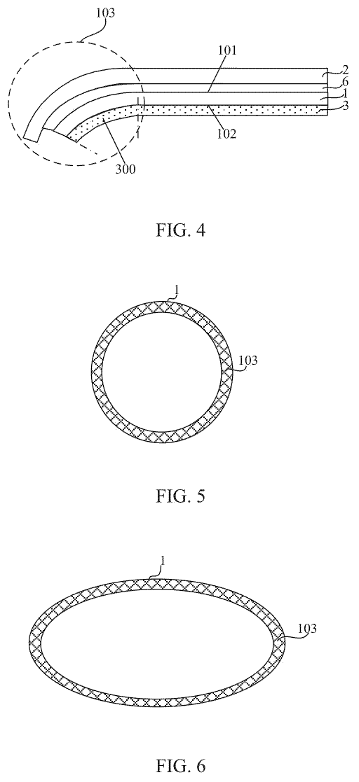

In view of the above technical problems, an embodiment of the present disclosure provides a display module which, as shown in FIGS. 3 and 4, includes a display panel 1; a cover plate 2 on a light-emitting side 101 of the display panel 1; and a heat dissipation layer 3 on a back side 102 of the display panel 1. The back side 102 faces away from the light-emitting side 101. Peripheral edges of the cover plate 2, edges of the display panel 1 and edges of the heat dissipation layer 3 are bent toward the back side 102 of the display panel 1 to form arc surface regions shapes matched with each other. The display panel 1 further includes a planar portion, and the edges of the display panel are arranged around the planar portion. At least part of an edge of an orthographic projection of the display module on a plane where the planar portion of the display panel 1 is located is arc. The heat dissipation layer 3 includes a stretchable structure 300 in each of arc surface regions 103 having arc edges.

Here, the planar portion of the display panel 1 refers to a planar region of the display panel 1. The at least part of the edge line of the orthographic projection of the display module on the plane where the planar portion of the display panel 1 is located is arc, which means that the display module has at least one corner including an arc edge line. In this embodiment, as shown in FIG. 3, the orthographic projection of the display module on the plane where the planar portion of the display panel 1 is located has a rounded rectangular shape with four rounded corners (where edge lines of the corners are circular arc lines). In some embodiments, as shown in FIGS. 5 and 6, the orthographic projection of the display module on the plane where the planar portion of the display panel 1 is located may also have a circular shape, an elliptical shape, or any other irregular shape. For the display module in FIGS. 5 and 6 in which the entire edge line of the orthographic projection is an arc, the stretchable structure 300 is disposed on the entire edge region of the heat dissipation layer 3.

By providing the stretchable structure 300 in the arc surface regions 103 having the arc edge of the heat dissipation layer 3, in the process of arranging the heat dissipation layer 3 in a planar film layer state to the back side 102 of the display panel 1 having the arc edges of the arc surface, the region having the arc edge of the heat dissipation layer 3 can be well fitted to the arc surface regions 103 having the arc edge of the display panel 1 through stretching and compression, so that the regions having the arc edge of the heat dissipation layer 3 can be smoothly bent and deformed from the planar state into an arc surface state that fits with the shape of the arc surface regions 103 having the arc edge of the display panel 1. In this process, the stretchable structure 300 can be compressed to well absorb a redundant area generated from the compressed heat dissipation layer 3, and can be stretched to increase a missing area of the stretched heat dissipation layer 3, so that pleats in the compressed heat dissipation layer 3 as well as cracks in the stretched heat dissipation layer 3 can be avoided, thereby preventing bubbles between the heat dissipation layer 3 and the display panel 1, as well as cracks in the display panel 1, and improving the quality of the entire display module.

In some embodiments, as shown in FIGS. 7 to 9, the heat dissipation layer 3 includes a thermal conductive film 31, and the stretchable structure 300 includes a through hole 301 in the thermal conductive film 31. The through holes 301 can be compressed to well absorb a redundant area generated from the compressed heat dissipation layer 3, and can be stretched to increase a missing area of the stretched heat dissipation layer 3, so that pleats in the compressed thermal conductive film 31 as well as cracks in the stretched thermal conductive film 31 can be avoided, thereby ensuring that the thermal conductive film 31 can timely transfer and release of the heat generated from the display panel 1.

In some embodiments, the thermal conductive film 31 is made of any one of copper, aluminum, silver, or gold. In some embodiments, the thermal conductive film 31 may also be made of other materials capable of conducting heat. In this embodiment, the thermal conductive film 31 is made of copper. Copper has good heat conduction and heat release performance, and a copper foil has better ductility, which is favorable to flexible arrangement of the heat dissipation layer 3.

In some embodiments, a plurality of through holes 301 are formed, and the plurality of through holes 301 are arranged in an array along an extending direction L of the arc edge. In other words, the plurality of through holes 301 are arranged in multiple rows along the extending direction L of the arc edge. Such an arrangement is beneficial to stretching and compression of the through holes 301 along the extending direction L of the arc edge of the display module, thereby avoiding pleats or cracks in the thermal conductive film 31 along the extending direction L of the arc edge of the display module generated in the process of disposing the thermal conductive film 31 on the back side of the display panel.

In some embodiments, an orthographic projection of each of the through holes 301 on the display panel 1 has any one or more shapes of a circle, an ellipse, a rectangle, a diamond or a regular polygon. Apparently, a shape of the orthographic projection of each of the through holes 301 on the display panel 1 is not limited to the above shapes, and may be any other shape. In this embodiment, the orthographic projection of each of the through holes 301 on the display panel 1 has a circular shape.

In some embodiments, as shown in FIG. 9, the through holes 301 are evenly spaced apart from each other in the arc surface region 103 having the arc edge. The through holes 301 have a same shape and a same cross sectional area in the arc surface region 103 having the arc edge.

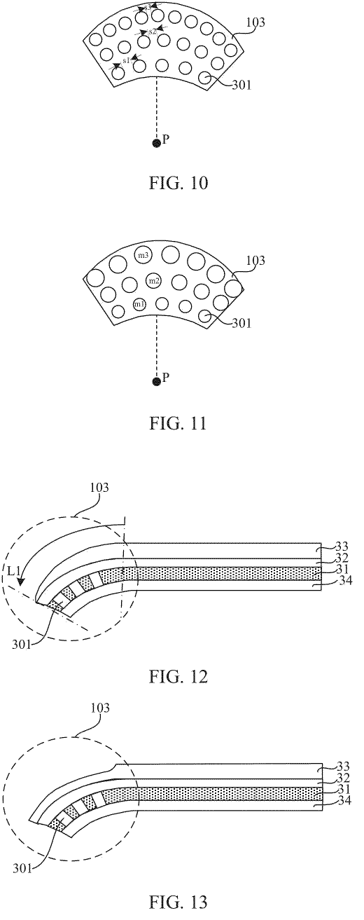

In some embodiments, as shown in FIG. 10, the through holes 301 have a same cross sectional area in the arc surface region 103 having the arc edge. A distance between the through holes 301 proximal to a center P of the heat dissipation layer 3 is a greater distance than a distance between the through holes 301 away from the center P of the heat dissipation layer 3. For example, in the arc surface region 103 having the arc edge, three rows of through holes 301 are arranged along a direction away from the center P of the heat dissipation layer 3, where a first row of through holes 301 have a same distance s1 between any two adjacent through holes 301, a second row of through holes 301 have a same distance s2 between any two adjacent through holes 301, and a third row of through holes 301 have a same distance s3 between any two adjacent through holes 301. The distance s1 between any two adjacent through holes of the first row of through holes 301 is greater than the distance s2 between any two adjacent through holes of the second row of through holes 301, and the distance s2 between any two adjacent through holes of the second row of through holes 301 is greater than the distance s3 between any two adjacent through holes of the third row of through holes 301. In the process of disposing the heat dissipation layer 3 on the back side 102 of the display panel 1, in the arc surface region 103 having the arc edge, along the direction away from the center P of the heat dissipation layer 3, the first and second rows of through holes 301 are subjected to a compression stress, the third row of through holes 301 are subjected to a tensile stress, and the stress gradually increases from the first row of through holes 301 to the third row of through holes 301. By setting the above distances between the through holes 301, different magnitudes of stress at different rows of through holes 301 can be effectively released through the density arrangement of the through holes 301, thereby avoiding pleats generated when the heat dissipation layer 3 is compressed or cracks generated when the heat dissipation layer 3 is stretched.

In some embodiments, as shown in FIG. 11, the through holes 301 have a same distance therebetween in the arc surface region 103 having the arc edge. A cross sectional area of the through holes 301 proximal to a center P of the heat dissipation layer 3 is smaller than a cross sectional area of the through holes 301 away from the center P of the heat dissipation layer 3. For example, in the arc surface region 103 having the arc edge, three rows of through holes 301 are arranged along a direction away from the center P of the heat dissipation layer 3, a first row of through holes 301 have a same cross sectional area ml, a second row of through holes 301 have a same cross sectional area m2, a third row of through holes 301 have a same cross sectional area m3. A cross sectional area m1 of the first row of through holes 301 is smaller than a cross sectional area m2 of the second row of through holes 301, and a cross sectional area m2 of the second row of through holes 301 is smaller than a cross sectional area m3 of the third row of through holes 301. In the process of disposing the heat dissipation layer 3 on the back side 102 of the display panel 1, in the arc surface region 103 having the arc edge, along the direction away from the center P of the heat dissipation layer 3, the first and second rows of through holes 301 are subjected to a compression stress, the third row of through holes 301 are subjected to a tensile stress, and the stress gradually increases from the first row of through holes 301 to the third row of through holes 301. By setting the cross sectional areas of the through holes 301, different magnitudes of stress in different rows of through holes 301 can be effectively released through the density arrangement of the through holes 301, thereby avoiding pleats generated when the heat dissipation layer 3 is compressed or cracks generated when the heat dissipation layer 3 is stretched.

In some embodiments, a size of each of the through holes 301 ranges from 0.5 to 1.5 mm. For a round through hole 301, the size of the round through hole 301 is a diameter of the circle. For a through hole 301 in other shapes, the size of the through hole 301 is a minimal radial dimension of the through hole 301. The above range of the size for the through holes 301 can be achieved through a conventional manufacture process.

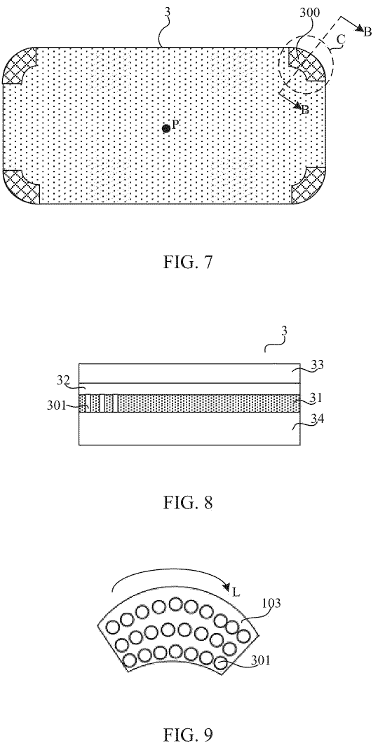

In some embodiments, as shown in FIG. 8, the heat dissipation layer 3 further includes an electromagnetic shielding film 32, which is disposed on a side of the thermal conductive film 31 away from the display panel 1, and covers at least the through holes 301 in the thermal conductive film 31. The thermal conductive film 31 is made of a metal thermal conducting material with certain ductility, so that the thermal conductive film 31 can play a certain role in electromagnetic shielding, and protect the display panel 1 from external electromagnetic interference. However, since the thermal conductive film 31 is provided with through holes 301, and the thermal conductive film 31 penetrates through the entire thickness of the thermal conductive film 31, electromagnetic interference cannot be shielded at the through holes 301, and external electromagnetic waves can easily interfere with the display panel 1 via the through holes 301. By at least covering the electromagnetic shielding film 32 on the through holes 301, it is possible to prevent external electromagnetic waves from interfering with the display panel 1 via the through holes 301, thereby ensuring normal display of the display panel 1.

In this embodiment, the electromagnetic shielding film 32 covers the entire thermal conductive film 31. With such arrangement, on one hand, the manufacture process of the electromagnetic shielding film 32 can be simplified, and on the other hand, compared with the solution in which the electromagnetic shielding film 32 covers only the through holes 301, the electromagnetic shielding film 32 is arranged on a side of the thermal conductive film 31, so that no step is formed on the side of the thermal conductive film 31, and the surface of the heat dissipation layer 3 with the electromagnetic shielding film 32 provided thereon can remain flat.

In some embodiments, the electromagnetic shielding film 32 is made of any one of copper, aluminum, silver, or gold. In some embodiments, the electromagnetic shielding film 32 has a thickness ranging from 15 µm to 30 µm. An electromagnetic shielding film 32 of the above material and thickness has certain stretchability, and can be stretched or retracted along with the thermal conductive film 31, so that no pleats or cracks will occur across the heat dissipation layer 3 in the process of attaching the heat dissipation layer 3 on the back side 102 of the display panel 1. It should be noted that the electromagnetic shielding film 32 may also be made of any other material that can play an electromagnetic shielding role and have certain stretchability.

In some embodiments, as shown in FIG. 8, the heat dissipation layer 3 further includes a protective film 33, which is disposed on a side of the electromagnetic shielding film 32 away from the display panel 1. An orthographic projection of the protective film 33 on the display panel 1 overlaps an orthographic projection of the electromagnetic shielding film 32 on the display panel 1. The protective film 33 can prevent the electromagnetic shielding film 32 from being corroded and damaged due to being exposed outside.

In some embodiments, the protective film 33 is made of polyolefin. A protective film 33 made of polyolefin has certain stretchability, and can be stretched or compressed along with the stretching or compression of the thermal conductive film 31 and the electromagnetic shielding film 32, so that no pleats or cracks will occur across the heat dissipation layer 3 in the process of disposing the heat dissipation layer 3 on the back side 102 of the display panel 1. Apparently, the protective film 33 may also be made of any other material with certain stretchability.

In some embodiments, as shown in FIG. 12, a portion of the protective film 33 in the arc surface region 103 having the arc edge has a gradually decreased thickness in a direction L1 from an end away from the arc edge toward the arc edge. With such arrangement, the stretchability of the portion of the protective film 33 in the arc surface region 103 having the arc edge can be further increased, so that the arc surface region 103 having the arc edge of the protective film 33 can be stretched or retracted along with the stretching or compression of the thermal conductive film 31 and the electromagnetic shielding film 32, and thus no pleats or cracks will occur across the heat dissipation layer 3 in the process of disposing the heat dissipation layer 3 on the back side of the display panel.

In some embodiments, as shown in FIG. 13, a portion of the protective film 33 in the arc surface region 103 having the arc edge has a smaller thickness than other portions of the protective film 33. In other words, the portion of the protective film 33 in the arc surface region 103 having the arc edge has a uniform/same and relatively small thickness, while other portions of the protective film 33 other than the portion in the arc surface region 103 having the arc edge have a uniform/same and relatively large thickness. With such arrangement, the portion of the protective film 33 in the arc surface region 103 having the arc edge has better stretchability than other portions of the protective film 33, so that the arc surface region 103 having the arc edge of the protective film 33 can be better stretched or retracted along with the stretching or compression of the thermal conductive film 31 and the electromagnetic shielding film 32, and thus no pleats or cracks will occur across the heat dissipation layer 3 in the process of the heat dissipation layer 3 being disposed on the back side of the display panel.

In some embodiments, as shown in FIG. 8, the heat dissipation layer 3 further includes an adhesive film 34, which is disposed on a side of the thermal conductive film 31 proximal to the display panel 1. An orthographic projection of the adhesive film 34 on the display panel 1 overlaps an orthographic projection of the electromagnetic shielding film 32 on the display panel 1. By providing the adhesive film 34, on one hand, the heat dissipation layer 3 can be securely attached to the back side 102 of the display panel 1, thereby simplifying the arrangement of the heat dissipation layer 3 on the back side 102 of the display panel 1; and on the other hand, the adhesive film 34 can play a certain buffering effect on the force generated when the heat dissipation layer 3 is attached to the back side 102 of the display panel 1, thereby preventing the display panel 1 from being damaged by the force generated when the heat dissipation layer 3 is attached.

In some embodiments, the adhesive film 34 is made of a stretchable adhesive material. For example, the adhesive film 34 is made of an adhesive material including a mixture of foam rubber and soft silica gel (or latex, or silica gel). An adhesive film 34 made of the above material has certain stretchability, and can be stretched or retracted along with the stretching or compression of the thermal conductive film 31 and the electromagnetic shielding film 32, so that no pleats or cracks will occur across the heat dissipation layer 3 in the process of the heat dissipation layer 3 being disposed on the back side 102 of the display panel 1. Apparently, the adhesive film 34 may also be made of any other adhesive material with certain stretchability.

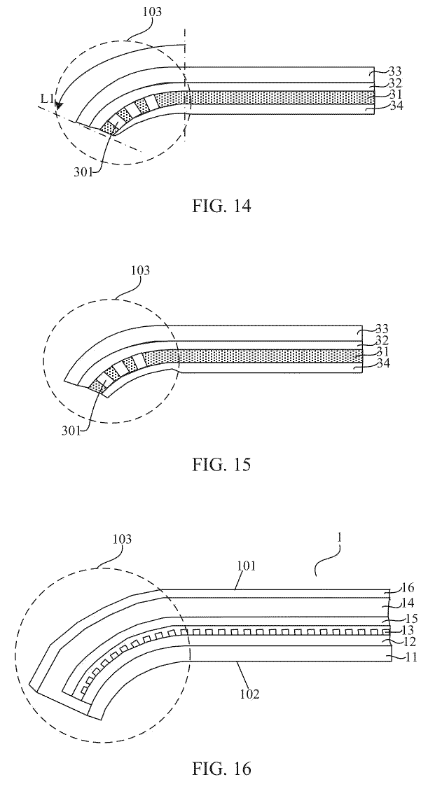

In some embodiments, as shown in FIG. 14, a portion of the adhesive film 34 in the arc surface region 103 having the arc edge has a gradually decreased thickness in a direction L1 from an end away from the arc edge toward the arc edge. With such arrangement, the stretchability of the portion of the adhesive film 34 in the arc surface region 103 having the arc edge can be further increased, so that the arc surface region 103 having the arc edge of the adhesive film 34 can be stretched or retracted along with the stretching or compression of the thermal conductive film 31 and the electromagnetic shielding film 32, and thus no pleats or cracks will occur across the heat dissipation layer 3 in the process of the heat dissipation layer 3 being disposed on the back side of the display panel.

In some embodiments, as shown in FIG. 15, a portion of the adhesive film 34 in the arc surface region 103 having the arc edge has a smaller thickness than other portions of the adhesive film 34. In other words, the portion of the adhesive film 34 in the arc surface region 103 having the arc edge has a same and relatively small thickness, while other portions of the adhesive film 34 other than the portion in the arc surface region 103 having the arc edge have a same and relatively large thickness. With such arrangement, the portion of the adhesive film 34 in the arc surface region 103 having the arc edge has better stretchability than other portions of the adhesive film 34, so that the arc surface region 103 having the arc edge of the adhesive film 34 can be better stretched or retracted accordingly with the stretching or compression of the thermal conductive film 31 and the electromagnetic shielding film 32, and thus no pleats or cracks will occur across the heat dissipation layer 3 in the process of the heat dissipation layer 3 being disposed on the back side of the display panel.

In some embodiments, as shown in FIG. 16, the display panel 1 includes a flexible base substrate 11, and a pixel circuit layer 12 and a light-emitting element 13 on the flexible base substrate 11. The pixel circuit layer 12 includes a pixel circuit and an insulating film layer between different electrode layers in the pixel circuit. The pixel circuit may be a driver circuit such as 7T1C or 5T1C. The light-emitting element 13 includes an organic electroluminescence element, a light-emitting diode, a micro light-emitting diode, or the like. The display panel 1 may be flexibly bent to fit an overall shape of the cover plate 2.

In some embodiments, not only the planar display region on the display side 101 of the display panel 1 can display images, but also both of the arc surface region 103 having the arc edge of the display panel 1 and the arc surface portion formed by bending the peripheral edge region toward the back side 102 of the display panel 1 can display images, so that bezel-less display of the display module cana be realized.

In some embodiments, only the planar display region on the display side 101 of the display panel 1 can display images, while both of the arc surface region 103 having the arc edge of the display panel 1 and the arc surface portion formed by bending the peripheral edge region toward the back side 102 of the display panel 1 cannot display images, so that narrow-bezel display of the display module can be realized.

In some embodiments, the display panel 1 further includes an encapsulation layer 14 and a touch electrode layer 15. The encapsulation layer 14 is disposed on a side of the pixel circuit layer 12 and the light-emitting element 13 away from the flexible base substrate 11, and an orthographic projection of the encapsulation layer 14 on the flexible base substrate 11 overlaps the entire pixel circuit layer 12 and the entire light-emitting element 13. Therefore, the pixel circuit layer 12 and the light-emitting element 13 on the flexible base substrate 11 are encapsulated and protected from external moisture and oxygen. The encapsulation layer 14 is formed by stacking a plurality of organic film layers and a plurality of inorganic film layers alternatively.

The display panel 1 further includes a touch electrode layer 15. The touch electrode layer 15 is disposed on a side of the encapsulation layer 14 proximal to the light-emitting element 13, and an insulating layer is disposed between the touch electrode layer 15 and the conductive electrode layer in the pixel circuit layer 12, so that the touch electrode layer 15 and the conductive electrode layer in the pixel circuit layer 12 are insulated from each other. In other words, in the display panel 1, the touch structure is designed according to a flexible multi-layer on cell (FMLOC) process . The FMLOC process includes fabricating a metal mesh touch electrode layer 15 on the encapsulation structure of the display panel 1 to realize the touch control of the display panel 1 without any external touch panel. The FMLOC process can reduce the thickness of the touch display panel 1, thereby facilitating bending and folding of the display panel 1; meanwhile, a bonding tolerance between the touch structure and the display panel 1 can be avoided, thereby reducing a bezel width of the display panel 1.

In some embodiments, the touch electrode layer may also be disposed on a side of the encapsulation layer away from the light-emitting element. That is, the display panel employs an external touch panel.

In some embodiments, the display panel 1 further includes a polarizer 16 on a side of the encapsulation layer 14 away from the touch electrode layer 15. The polarizer 16, such as a circular polarizer, can eliminate not only reflection of external light by the conductive metal film layers in the pixel circuit layer 12, but also reflection of external light by the touch electrode layer 15. The principle of eliminating reflection by the polarizer 16 is: after external incident light passes through the circular polarizer, the external incident light becomes circular polarized light, and the rotation direction of the circular polarized light changes after the circular polarized light is reflected by a metal electrode. The reflected light, when passing through the circular polarizer again, cannot be emitted from the circular polarizer, so that the reflected light can be eliminated. Meanwhile, the contrast of the display panel 1 in bright environments can also be increased.

In some embodiments, as shown in FIG. 4, the display panel 1 and the cover plate 2 are attached and fixed to each other via an optical clear adhesive (OCA) 6 formed therebetween. The OCA 6 has the characteristics of being colorless and clear, light transmittance of more than 90%, good bonding strength, being curable at room temperature or intermediate temperature, small curing shrinkage and the like, as well as high weather resistance, high water resistance, high temperature resistance, ultraviolet resistance, easily controlled thickness, uniform distance, and no yellowing, peeling and deterioration after long-term use.

Based on the above structure of the display module, an embodiment of the present disclosure further provides a method for manufacturing the display module, including: manufaturing a cover plate such that a peripheral edge region of the cover plate is bent towards a side of a plate surface of the cover plate to form an arc surface; manufacturing a display panel; manufacturing a heat dissipation layer; disposing the display panel on an inner side of the cover plate, such that the display panel is shape-matched with the cover plate, wherein the inner side of the cover plate is an inner side of the arc surface, and the cover plate is disposed on a light-emitting side of the display panel, and the display panel includes a planar portion and a peripheral edge region surrounding the planar portion; and disposing a heat dissipation layer on a back side of the display panel, such that the heat dissipation layer is shape-matched with the display panel, and the back side of the display panel faces away from the light-emitting side of the display panel.

At least part of an edge of an orthographic projection of the display module on a plane where the planar portion of the display panel is located is arc. The manufacturing the heat dissipation layer includes forming a stretchable structure in an arc surface region having an arc edge of the heat dissipation layer.

In some embodiments, the cover plate may be a glass cover plate, but apparently, the cover plate may also made of other materials. The flexible display panel is attached to the inner side of the cover plate through an attachment jig. When the display panel is attached to the inner side of the cover plate, the display panel is shape-matched with the cover plate. The cover plate covers the entire light-emitting side of the display panel to protect the light-emitting side of the display panel, while ensuring normal emission of display light of the display panel through the cover plate and thus normal display of the display panel.

In some embodiments, the heat dissipation layer is attached to the back side of the display panel through an attachment jig. In the arc surface region having the arc edge of the heat dissipation layer, by properly compressing a portion of the stretchable structure, proximal to the center of the heat dissipation layer, in the arc surface region , and properly stretching a portion of the stretchable structure, away from the center of the heat dissipation layer, in the arc surface region during the attaching process, the arc surface region having the arc edge of the heat dissipation layer can be shape-matched with and closely attached to the arc surface region having the arc edge of the display panel, no pleats exist in the arc surface region of the heat dissipation layer, and no bubbles or other defects will exist between the heat dissipation layer and the display panel. The specific attaching process belongs to a conventional process, and thus is not described in detail here.

In some embodiments, the manufacture of the heat dissipation layer includes preparing a thermal conductive film; and the manufacture of the stretchable structure includes forming a through hole in the thermal conductive film through an etching or punching process.

The etching process includes: coating a photoresist on the formed thermal conductive film, and then forming a pattern of the through hole through exposure, development and wet etching processes. The etching process is a conventional process and thus is not described in detail here. The punching process includes punching the thermal conductive film in the region of the through hole according to a punching pattern, and removing the thermal conductive film in the region of the through hole to form the through hole. Apparently, the punching process may include using a mask to define a pattern of the through hole, and then punching and removing the pattern of the through hole defined by the mask by using a punching device to form the pattern of the through hole. The punching process is also a well-established conventional process, and thus is not described in detail here.

According to the display module provided in the embodiments of the present disclosure, by forming the stretchable structure in the arc surface region having the arc edge of the heat dissipation layer, in the process of arranging the heat dissipation layer in a planar film layer state to the back side of the display panel at the arc edges of the display panel, the region having the arc edge of the heat dissipation layer can be well shape matched to the arc surface region having the arc edge of the display panel through stretching and compression, so that the region having the arc edge of the heat dissipation layer can be smoothly bent and deformed from the planar state into an arc surface state that fits the shape of the arc surface region having the arc edge of the display panel. In this process, the stretchable structure can be compressed to well absorb a redundant area generated from the compressed heat dissipation layer, and be stretched to increase a missing area of the stretched heat dissipation layer, so that pleats generated in the compressed heat dissipation layer as well as cracks generated in the stretched heat dissipation layer can be avoided, thereby preventing bubbles between the heat dissipation layer and the display panel, as well as cracks in the display panel, and improving the quality of the entire display module.

An embodiment of the present disclosure further provides a display apparatus including the display module as described in any one of the above embodiments.

By adopting the display module in the above embodiments, the manufacture quality and display quality of the display apparatus can be improved.

The display panel in the embodiments of the present disclosure may be any product or component with a display function, such as an OLED panel, an OLED television, an LED panel, an LED television, a Mini LED panel, a Mini LED television, a monitor, a mobile phone, a navigator, or the like.

It will be appreciated that the above implementations are merely exemplary implementations for the purpose of illustrating the principle of the present disclosure, and the present disclosure is not limited thereto. It will be apparent to one of ordinary skill in the art that various modifications and variations may be made without departing from the spirit or essence of the present disclosure. Such modifications and variations should also be considered as falling into the protection scope of the present disclosure.

1. A display module, comprising:
a display panel;
a cover plate on a light-emitting side of the display panel; and
a heat dissipation layer on a back side of the display panel; wherein the back side faces away from the light-emitting side; wherein
edges of the cover plate, edges of the display panel and edges of the heat dissipation layer are bent toward the back side of the display panel to form arc surface regions with shapes matched with each other;
the display panel further comprises a planar portion, and the edges of the display panel surround the planar portion,
at least part of an edge of an orthographic projection of the display module on a plane where the planar portion of the display panel is located is arc, and
the heat dissipation layer comprises a stretchable structure in the arc surface region having an arc edge of the heat dissipation layer.

2. The display module according to claim 1, wherein
the heat dissipation layer comprises a thermal conductive film, and
the stretchable structure comprises a through hole in the thermal conductive film.

3. The display module according to claim 2, wherein
the stretchable structure comprises a plurality of through holes, and
the plurality of through holes are arranged in an array along an extending direction of the arc edge.

4. The display module according to claim 3, wherein the plurality of through holes are evenly spaced apart from each other in the arc surface region having the arc edge.

5. The display module according to claim 3, wherein
the through holes in the arc surface region having the arc edge have a same cross sectional area, and
a distance between the through holes proximal to a center of the heat dissipation layer is greater than a distance between the through holes away from the center of the heat dissipation layer.

6. The display module according to claim 3, wherein
the through holes in the arc surface region having the arc edge have a same distance therebetween, and
a cross sectional area of the through holes proximal to a center of the heat dissipation layer is smaller than a cross sectional area of the through holes away from the center of the heat dissipation layer.

7. The display module according to claim 3, wherein a size of each of the plurality of through holes ranges from 0.5 to 1.5 mm.

8. The display module according to claim 7, wherein an orthographic projection of each of the plurality of through holes on the display panel has any one or more shapes of a circle, an ellipse, a rectangle, a diamond or a regular polygon.

9. The display module according to claim 2, wherein the thermal conductive film comprises any one of copper, aluminum, silver, or gold.

10. The display module according to claims 2 , wherein
the heat dissipation layer further comprises an electromagnetic shielding film, and
the electromagnetic shielding film is on a side of the thermal conductive film away from the display panel, and covers at least the through hole in the thermal conductive film.

11. The display module according to claim 10, wherein the electromagnetic shielding film comprises any one of copper, aluminum, silver, or gold.

12. The display module according to claim 10, wherein
the heat dissipation layer further comprises a protective film,
the protective film disposed is on a side of the electromagnetic shielding film away from the display panel, and
an orthographic projection of the protective film on the display panel overlaps an orthographic projection of the electromagnetic shielding film on the display panel.

13. The display module according to claim 12, wherein a portion of the protective film in the arc surface region having the arc edge has a gradually decreased thickness in a direction from an end away from the arc edge toward the arc edge.

14. The display module according to claim 12, wherein a portion of the protective film in the arc surface region having the arc edge has a smaller thickness than other portions of the protective film, or the protective film comprises polyolefin.

15. (canceled)

16. The display module according to claim 12, wherein
the heat dissipation layer further comprises an adhesive film,
the adhesive film is on a side of the thermal conductive film proximal to the display panel, and
an orthographic projection of the adhesive film on the display panel overlaps an orthographic projection of the electromagnetic shielding film on the display panel.

17. The display module according to claim 16, wherein a portion of the adhesive film in the arc surface region having the arc edge has a gradually decreased thickness in a direction from an end away from the arc edge toward the arc edge.

18. The display module according to claim 16, wherein a portion of the adhesive film in the arc surface region having the arc edge has a smaller thickness than other portions of the adhesive film, or the adhesive film comprises a stretchable adhesive material.

19. (canceled)

20. A display apparatus, comprising the display module according to claims 1.

21. A method for manufacturing a display module, comprising:
preparing a cover plate, such that edges of the cover plate are bent towards a side of the cover plate to form an arc surface;
preparing a display panel;
preparing a heat dissipation layer;
disposing the display panel on an inner side of the cover plate with the display panel being shape-matched with the cover plate; wherein the inner side of the cover plate is an inner side of the arc surface, and the cover plate is on a light-emitting side of the display panel, and the display panel comprises a planar portion and edges surrounding the planar portion; and
disposing a heat dissipation layer on a back side of the display panel with the heat dissipation layer being shape-matched with the display panel; wherein the back side of the display panel faces away from the light-emitting side of the display panel; wherein
at least part of an edge of an orthographic projection of the display module on a plane where the planar portion of the display panel is located is arc, and
preparing the heat dissipation layer comprises: preparing a stretchable structure in the arc surface region having an arc edge of the heat dissipation layer.

22. The method for manufacturing a display module according to claim 21, wherein
preparing the heat dissipation layer comprises preparing a thermal conductive film, and
preparing the stretchable structure comprises: forming a through hole in the thermal conductive film through an etching or punching process.
